(19) United States
(12) Patent Application Publication
(10) Pub. No.: US 2026/0293641 A1
(43) Pub. Date: Sep. 24, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Ryo OKUHATA, Tokyo (JP); Koichiro NISHIZAWA, Tokyo (JP); Tomoyuki MORITA, Tokyo (JP); Tomoaki TOKUHISA, Tokyo (JP); Toshikazu SHIMIZU, Tokyo (JP)

(73) Assignee: Mitsubishi Electric Corporation, Tokyo (JP)

(21) Appl. No.: 19/473,475

(22) PCT Filed: May 29, 2023
(86) PCT No.: PCT/JP2023/019866

§ 371 Date: Oct. 7, 2025

(51) Int. Cl. H10W 20/20; H10D 30/47; H10D 62/83; H10D 62/832; H10D 62/85; H10D 64/27; H10W 20/00

(52) U.S. Cl. CPC H10W 20/215; H10D 62/83; H10D 62/8325; H10D 62/85; H10D 62/8503; H10W 20/0261; H10W 20/213; H10D 30/475; H10D 64/411

(57) ABSTRACT

A semiconductor device according to the present application is configured to includes a substrate of a semiconductor material, a front-face electrode formed on one face of the substrate, and a solid via having a covering layer made of gold that has an opening on the other face of the substrate, covers an inner wall of a cylindrical hole having a bottom face as the front-face electrode, and forms a recessed portion recessed from a side of the opening toward the bottom face, and a filling layer made of any one of copper, silver, nickel, tin, and gold, the gold having a crystal grain size larger than that of the covering layer, the filling layer filling the recessed portion.

### TECHNICAL FIELD

The present application relates to a semiconductor device and a method of manufacturing a semiconductor device.

### BACKGROUND ART

In a semiconductor device having an electrode (via) penetrating the semiconductor substrate from the front face to the rear face thereof, by filling the inside of the via with copper (Cu) plating usually referred to as Cu via filling, it is expected to improve electrical connection, high-frequency characteristics, and heat dissipation.

Via filling using copper plating is carried out through electroplating, which requires precise control over the composition of the plating solution, the applied voltage waveform, and the stirring of the solution, and the like (refer to, for example, Patent Document 1). Additionally, due to a concern about the degradation of electrical properties caused by the diffusion of copper into the semiconductor interior, it is necessary to form a diffusion barrier layer on the inner wall of the via (refer to, for example, Patent Document 2).

### PRIOR ART DOCUMENT

### Patent Document

Patent Document 1: Japanese Patent Application Laid-Open No. 2014-095104 (paragraphs 0042 to 0050, Table 1)
Patent Document 2: Japanese Patent Application Laid-Open Publication (Translation of PCT Application) No. 2013-532903 (paragraph 0039, FIG. 13)

### SUMMARY OF THE INVENTION

### Problems to be Solved by the Invention

However, in the Cu via filling through electroplating, precise control of the plating process (such as the composition of the plating solution, the applied voltage waveform, and the stirring of the solution) is required, leading to issues such as excessive equipment investment and increased costs for process management. Furthermore, the diffusion barrier layer requires materials like conductive metal nitride, which involve complex formation processes and are challenging to handle. This also results in problems of excessive equipment investment and increased costs for process management, and the like.

The present application discloses a technique for solving the above-described problems, and an object thereof is to obtain a semiconductor device having good electrical connection and heat dissipation in the thickness direction at low cost.

### Means for Solving the Problems

A semiconductor device disclosed in the present application includes a substrate made of a semiconductor material, a wiring member formed on one face of the substrate, and a solid via having a first plating layer made of gold that has an opening on the other face of the substrate, covers an inner wall of a cylindrical hole having a bottom face as the wiring member, and forms a recessed portion recessed from a side of the opening toward the bottom face, and a second plating layer made of any one of copper, silver, nickel, tin, and gold, the gold having a crystal grain size larger than that of the first plating layer, the second plating layer filling the recessed portion.

A method of manufacturing a semiconductor device disclosed in the present application includes steps of forming a wiring member on one face of a substrate made of a semiconductor material and forming a cylindrical hole that has an opening on the other face of the substrate and has the wiring member as a bottom face, forming a first plating layer of gold by electroless plating so as to cover an inner wall of the cylindrical hole and form a recessed portion recessed from a side of the opening toward the bottom face, and forming a second plating layer of any one of copper, silver, nickel, tin, and gold by electroplating so as to fill the recessed portion.

### Advantageous Effect of Invention

According to a semiconductor device or a method of manufacturing a semiconductor device disclosed in the present application, since a gold covering layer is formed on the inner wall of the via in a simple process without requiring excessive equipment investment, a semiconductor device having good electrical connection and heat dissipation in the thickness direction can be obtained at low cost.

### BRIEF DESCRIPTION OF THE DRAWINGS

FIG. 1 is an end view showing a structure of a via in a semiconductor device according to Embodiment 1.

FIG. 2 is an end view showing a structure of the semiconductor device according to Embodiment 1.

FIG. 3 is a flowchart for describing a manufacturing method for the semiconductor device according to Embodiment 1.

FIG. 4 is an end view showing a structure of a covering layer of the via during a via filling process in the semiconductor device according to Embodiment 1.

FIG. 5 is a diagram showing a cross-section of a scanning electron microscope (SEM) image during the via filling process in the semiconductor device according to Embodiment 1.

FIG. 6 is a schematic end view showing a state of each of stages during formation of the covering layer in the via filling process of the semiconductor device according to Embodiment 1.

FIG. 7 is an end view showing a structure of a via in a semiconductor device according to a variation of Embodiment 1.

FIG. 8 is an end view showing a structure of a via in a semiconductor device according to a comparative example.

FIG. 9 is a diagram showing a cross-sectional SEM image during a via filling process in the semiconductor device of the comparative example.

FIG. 10 is an end view showing a structure before formation of a filling layer in a via filling process of a semiconductor device according to Embodiment 2.

FIG. 11 is a flowchart for describing a manufacturing method for the semiconductor device according to Embodiment 2.

FIG. 12 is an end view showing a structure of a via in the semiconductor device according to Embodiment 2.

FIG. 13 is an end view showing a structure of a via in a semiconductor device according to Embodiment 3.

FIG. 14 is an end view showing a structure of a via in a semiconductor device according to a variation of Embodiment 3.

FIG. 15 is an end view showing a structure of a via in a semiconductor device according to Embodiment 4.

FIG. 16 is an end view showing a structure of a via in a semiconductor device according a variation of Embodiment 4.

FIG. 17 is an end view showing a structure of a via in a semiconductor device according to Embodiment 5.

FIG. 18 is an end view showing a structure of a via in a semiconductor device according to a variation of Embodiment 5.

FIG. 19 is an end view showing a structure of a via in a semiconductor device according to Embodiment 6.

FIG. 20 is an end view showing a structure of a via in a semiconductor device according to a variation of Embodiment 6.

FIG. 21 is an end view showing a structure of a via in a semiconductor device according to Embodiment 7.

FIG. 22 is an end view showing a structure of a via in a semiconductor device according toa variation of Embodiment 7.

### MODE FOR CARRYING OUT INVENTION

### Embodiment 1

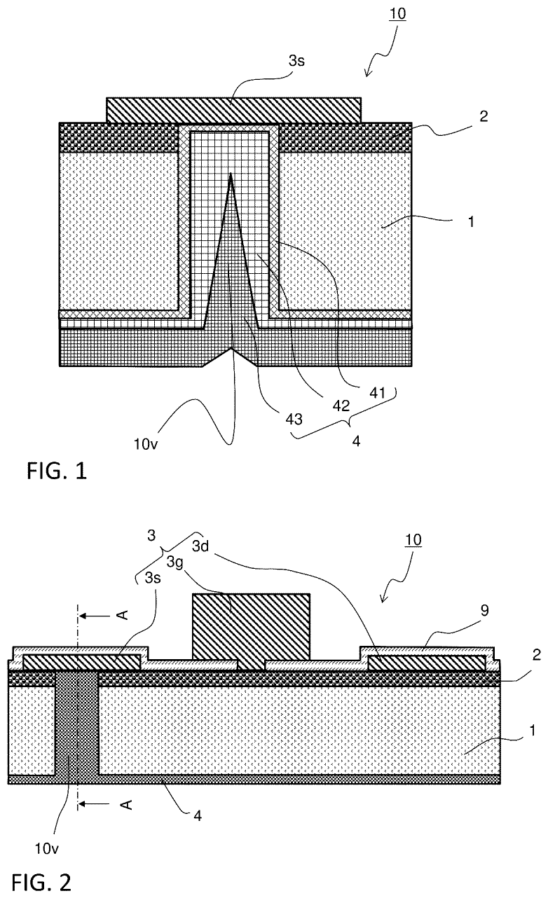

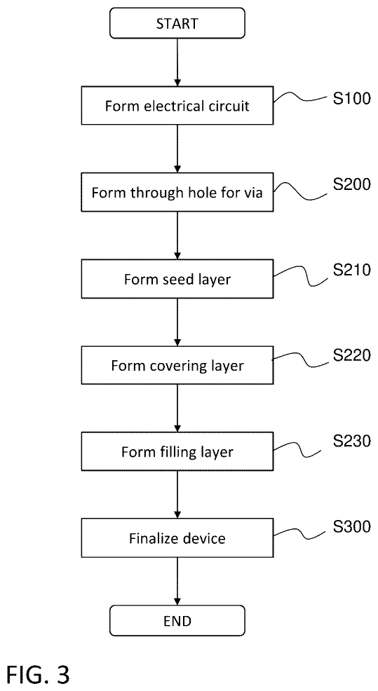

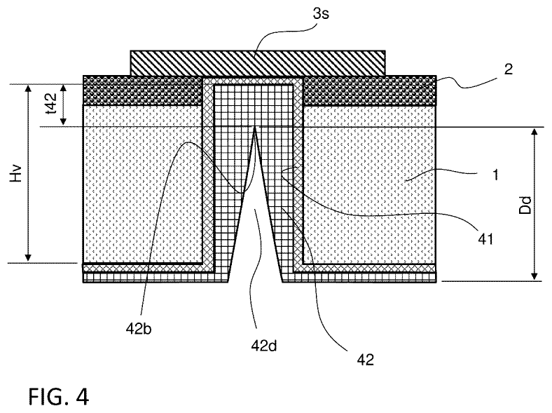

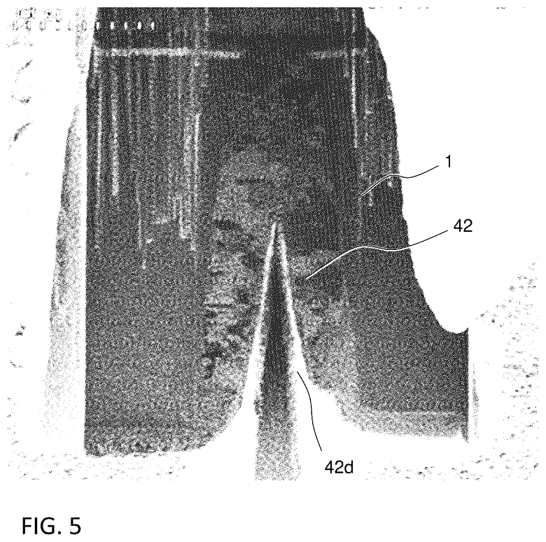

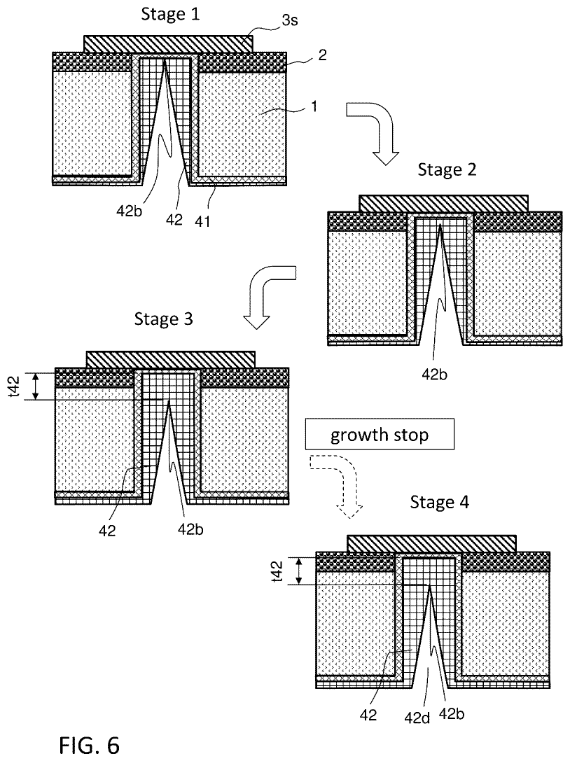

FIG. 1 to FIG. 9 are diagrams for describing a semiconductor device and a method of manufacturing the semiconductor device according to Embodiment 1, FIG. 1 is an end view corresponding to a line A-A of FIG. 2 to be described later for describing a structure of a via of the semiconductor device, and FIG. 2 is an end view for describing a structure of the semiconductor device. Further, FIG. 3 is a flowchart for describing a method of manufacturing the semiconductor device, FIG. 4 is an end view for describing a structure of a covering layer of the via of the semiconductor device after a covering layer is formed, which corresponding to FIG. 1 before a filling layer is formed in a via filling process, and FIG. 5 is a cross-sectional SEM image at a stage in which the same covering layer as that in FIG. 4 is formed in the via filling process. Furthermore, FIG. 6 is a schematic end view showing a state of each stage during formation of the covering layer in the via filling process of the semiconductor device according to Embodiment 1.

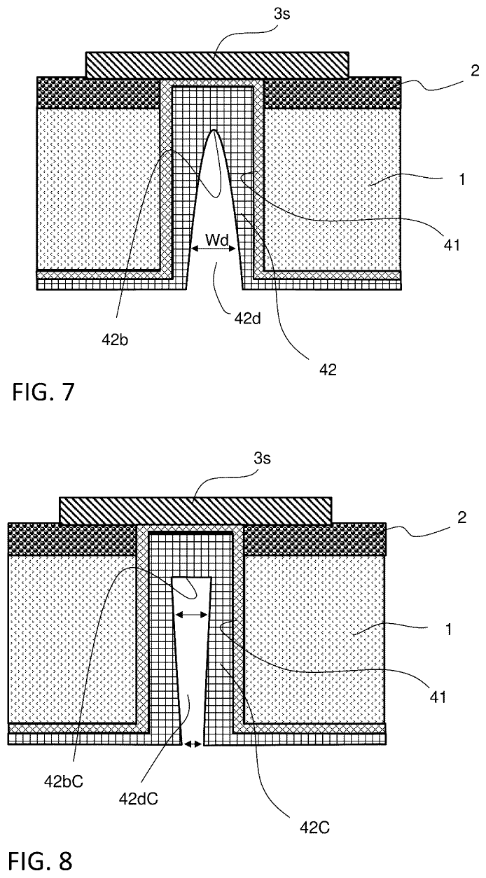

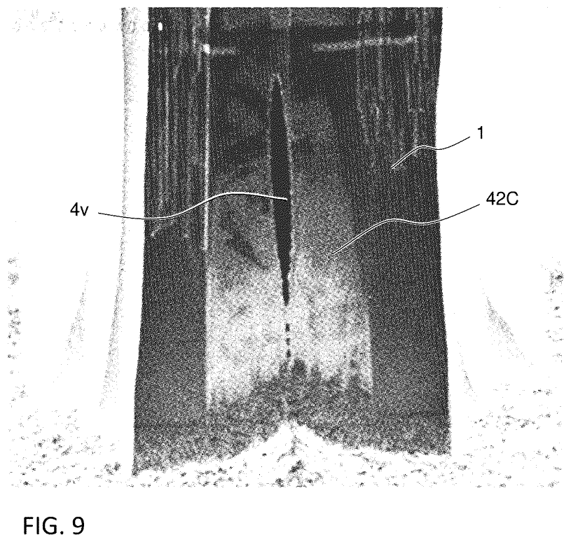

In addition, FIG. 7 is an end view corresponding to FIG. 4 of a stage after forming a covering layer, for describing a structure of a via of a semiconductor device according to a variation. On the other hand, FIG. 8 is an end view at a stage after forming a covering layer for describing a structure of a via of a semiconductor device according to a comparative example, and FIG. 9 is a cross-sectional SEM image at a stage after forming the same covering layer as that of FIG. 8 in the via filling process.

The semiconductor device 10 according to Embodiment 1 is assumed to be, for example, a semiconductor device referred to as a high electron mobility transistor (HEMT). As shown in FIG. 1 and FIG. 2, a case where a via 10v is formed from the rear face directly below a source electrode 3s on the front face (upper face in the figure) will be described as an example. Note that the via 10v shown in FIG. 1 is a detailed view of the via 10v formed directly below the source electrode 3s in FIG. 2, but the via 10v does not necessarily need to be directly below the source electrode 3s, and should be positioned directly below a conductive layer (wiring member) formed on the front face, including an interconnect pattern.

In the semiconductor device 10, there is an epitaxially grown layer 2 on a substrate 1 of silicon carbide (SiC), on which there are the source electrode 3s, a drain electrode 3d, and a gate electrode 3g (collectively referred to as a front-face electrode 3). The via 10v is formed directly below the source electrode 3s, with the source electrode 3s serving as an etching stop layer. A metal layer is formed along an inner wall of the via 10v, and a covering layer 42 and a filling layer 43 are formed in this order using the metal layer as a seed layer 41 to form a filling part 4, thereby achieving the via filling.

Note that, in Embodiment 1 and the following embodiments, a gallium nitride (GaN) HEMT on the substrate 1 of silicon carbide will be described as an example, but this is not a limitation. For example, the same effect can be obtained in other semiconductor substrates like compound semiconductors such as indium phosphide (InP), gallium nitride, and germanium silicide (SiGe), and silicon (Si)-based semiconductors. This is because gold (Au) constituting the covering layer 42 of the via 10v is formed on the seed layer 41, and thus it does not depend on the element type of the substrate 1.

Next, details of the structure of the semiconductor device 10 according to Embodiment 1 will be described together with a manufacturing method with reference to a flowchart of FIG. 3. First, on the front face (upper face in FIG. 1 and FIG. 2) side of the substrate 1 made of a SiC single crystal, epitaxial growth, formation of a metal film, an insulating film, and transfer patterning are repeatedly performed by a wafer process, thereby forming an electric circuit on the front face (step S100). Note that the wafer process is performed with a wafer being 0.35 mm or 0.5 mm thick in a disk shape having diameters of 4 to 8 inches.

First, the epitaxially grown layer 2 is formed on the substrate 1. In the case of the gallium nitride HEMT, a stacked structure in which an aluminum gallium nitride (AlGaN) layer is stacked on a gallium nitride layer is typically employed. Next, the source electrode 3s, the drain electrode 3d, and the gate electrode 3g are formed. For the source electrode 3s and the drain electrode 3d, for example, a stacked structure of titanium/aluminum/gold (Ti/Al/Au), titanium/aluminum/nickel/gold (Ti/Al/Ni/Au), or the like is used. A stacked structure of titanium/platinum/gold (Ti/Pt/Au) or the like is used for the gate electrode 3g.

Thereafter, the source electrode 3s, the drain electrode 3d, and the gate electrode 3g are protected by an insulating film 9 made of, for example, silicon nitride (SiN). Alternatively, after the source electrode 3s and the drain electrode 3d are formed and protected by the insulating film 9, only the portion thereof to be the gate electrode 3g may be opened by dry etching to form the gate electrode 3g, and the entire surface may be protected again by the insulating film 9. After that, an electrode for wiring may be further formed. For the electrode for wiring, gold electroplating or the like is used.

When the wafer process on the front face is completed, the front side of the wafer is bonded to a support substrate using a wax material for processing the rear face (lower surface in FIG. 1 and FIG. 2). At this time, a tape material may be used instead of the wax material, and the thickness of the wax material is, for example, 20 μm. The rear face of the wafer is ground and polished with the wafer attached to the support substrate. For example, the thickness of the substrate is reduced to 50 μm, which improves heat dissipation and high-frequency characteristics of the device.

Next, a via processing process (step S200 to step S230) is performed. In order to form the via 10v that is an electrode penetrating the substrate 1, a resist material is applied by a spin coater, and then the resist is removed only from a portion to be processed through transfer and development patterning. For example, a substrate etching process is performed by inductively coupled plasma (ICP) dry etching to form a through hole for the via 10v (step S200).

When the through hole is formed, the applied resist material is removed by immersion in a stripping solution. Then, it is possible to obtain a rear face side of the substrate 1 with the inner surface of the through hole serving as the via 10v of the substrate 1 exposed. The smaller the via 10v is, the higher the freedom of layout is, which is advantageous. However, if the via is too small, etching does not proceed when the through hole is formed, and the substrate 1 cannot be penetrated. For example, the through hole is formed in a cylindrical shape of φ50 μm. Here, the aspect ratio (via depth/via diameter) of the via 10v (through hole) is 1, but it varies depending on the thickness of the substrate and the via shape, and can be implemented in the range of 1 to 5.

The seed layer 41 is formed so as to cover the inner wall of the formed through hole (step S210). The seed layer 41 is formed, for example, by stacking a gold layer having a thickness 200 nm on a titanium layer having a thickness 50 nm in contact with the substrate 1. The titanium layer is a film inserted to improve the adhesion between the gold layer, which is the main part of the seed layer 41, and the substrate 1, and titanium nitride, tantalum (Ta), tungsten (W), chromium (Cr), or the like may be used instead of titanium. In addition, a platinum layer may be inserted between the titanium layer and the gold layer, and in this case, for example, a thickness 50 nm of the titanium layer, a thickness 50 nm of the platinum layer, and a thickness 200 nm of the gold layer are used. Further, an insulating layer may be inserted between the substrate 1 and the seed layer 41.

In order to promote a deposition reaction of electroless gold plating in the next process of forming the covering layer 42, it is necessary to cover the deposition surface of the seed layer 41 with a catalyst metal. When the surface of the seed layer 41 is formed as a gold layer, an electroless plating reaction starts. In addition to gold, silver (Ag), copper (Cu), palladium (Pd), platinum, nickel, ruthenium (Ru), tin (Sn), or the like may be used.

On the other hand, in the case of a metal surface having a weak catalytic power, the electroless plating reaction can be initiated by adding a process of immersing the metal surface in a pretreatment solution containing a catalyst metal ion as a pretreatment for the electroless plating to apply a catalyst. Once the plating reaction is started, gold itself, which is a deposited metal, serves as a catalyst, and thus the reaction can be continued to obtain a gold plating film (autocatalytic electroless plating).

Since the seed layer 41 is interposed between the substrate 1 and the covering layer 42 of gold, the seed layer 41 does not need to function as a barrier layer for preventing copper diffusion, which is a concern described in Patent Document 2. Therefore, it is not necessary to use a material whose formation process is complicated and which is difficult to handle, such as a conductive metal nitride like titanium nitride (TiN), tantalum nitride (TaN), tungsten nitride (WN), or titanium aluminum nitride (TiAlN).

When the seed layer 41 is formed, as shown in FIG. 4, the covering layer 42 of gold covering the seed layer 41 and having a recessed portion 42d opened toward the rear face side is formed by an electroless gold plating method (step S220). The figure shows an example of forming the conical recessed portion 42d having a V-shaped cross-sectional shape and passing through the axial center of the through hole. The formation of the conical recessed portion 42d can be achieved by adjusting an additive in a solution for the electroless gold plating within an appropriate range. Note that the additive has a function of suppressing plating deposition on the opening side (lower side in the figure) and preferentially depositing gold in the seed layer 41 from the bottom face (upper side in the figure) and the inner peripheral surface.

As shown in the cross-sectional SEM image of FIG. 5, the covering layer 42 can be formed so as to have the conical recessed portion 42d by the above-described method. Here, a thickness t42 (refer to FIG. 4) from the bottom of the via to the apex of the conical shape (bottom portion 42b of the recessed portion 42d) is preferably one fourth or more of a via height Hv. That is, a depth Dd of the recessed portion 42d is preferably less than 4/3 of the via height Hv. In this way, when the filling layer 43 is formed by the subsequent electroplating, the shape of the via filling can be achieved without occurrence of a void.

Note that, in FIG. 4, a dimension obtained by subtracting the thickness of the seed layer 41 from the thickness of the substrate 1 including the epitaxially grown layer 2 is drawn as the via height Hv, but the thickness of the seed layer 41 is negligibly small as compared with the thickness of the substrate 1. Thinner than the substrate 1. Therefore, the sum of the thickness of the substrate 1 and the thickness of the epitaxially grown layer 2 is defined as the above-described via height Hv. On the other hand, it is desirable that the thickness t42 is less than or equal to half of the via height Hv. When the thickness t42 is larger than half of the via height Hv, the amount of additive in the plating solution decreases, and the risk of the via opening being blocked as shown in FIG. 9 increases. In addition, since the amount of the additive is small, the thickness of the covering layer 42 on the rear face of the wafer becomes too large.

As described above, the vertical growth in the plating can be suppressed by the additive. Therefore, as shown in FIG. 6, when the plating grows in the order of Stage 1, Stage 2, and Stage 3 up to the thickness t42 determined by the addition amount of the additive, the gold plating does not grow even if the wafer is immersed in the electroless plating solution for, for example, 2 hours (from Stage 3 to Stage 4). Therefore, in each of the multiple through holes within the substrate face, it is possible to form the covering layer 42 having the recessed portion 42d uniformly with the same thickness t42.

After the covering layer 42 is formed, the filling layer 43 of gold having a grain size larger than that of the covering layer 42 formed by the electroless plating is formed by the electroplating so as to fill the recessed portion 42d shown in FIG. 1 (step S230). Thereby, the solid via 10v in which the inside of the through hole is filled with gold is formed. In order to efficiently supply gold ions into the recessed portion 42d, a pulse voltage may be applied. In the opening end of the via 10v (face on the lower side in the figure), that is, in the filling layer 43, there is a possibility that a recess is generated reflecting the recessed portion 42d of the covering layer 42, but the presence or absence and the shape of the recess do not matter.

Since the via 10v is completely filled with the filling layer 43 formed by the electroplating, high-frequency characteristics and heat dissipation are improved. When the film thickness of the gold on the rear face (lower side in the figure) of the wafer becomes too large by completely filling the via 10v, etching may be performed until a desired thickness is obtained. For the dry etching, for example, argon (Ar) ion milling or the like is used, and for the wet etching, for example, iodine (I)-based wet etching or the like is used.

Finally, the support substrate is peeled off from the wafer by heating the support substrate and the wafer on a hot plate at 100 degree C. for 1 minute or more to melt the wax material and by sliding the support substrate and the wafer relative to each other in parallel to the wafer surface. Then, the wax material on the surface is removed by immersion in acetone heated to 50 degree C. for 10 minutes to finish the device (step S300), and the removability is better as the temperature is higher and the immersion time is longer.

### Variation

Note that the recessed portion 42d of the covering layer 42 does not necessarily have to have a V-shaped (conical) cross-section as shown in FIG. 4, and may have a curved recessed shape as shown in FIG. 7 of the variation. An opening width Wd of the recessed portion 42d of the covering layer 42 may be formed so as to decrease toward the bottom portion 42b, and the bottom portion 42b may not be sharp.

### COMPARATIVE EXAMPLE

On the other hand, as shown in a comparative example of FIG. 8, it is undesirable for the recessed portion 42dC of the covering layer 42C to have an overhang shape where the opening width Wd increases toward the bottom 42bC. This is because, when the electroplating is performed to form the filling layer 43C in this condition, the opening of the recessed portion 42dC is blocked, resulting in a void inside the via. If the additive is not used, as shown in FIG. 9, the recessed portion 42dC has an overhang shape, the opening of the via is closed first, and a void 4v is generated. Note that, in the comparative example (FIG. 8 and FIG. 9), the portions corresponding to those in the embodiment are distinguished by adding “C” to the end of the reference numerals.

That is, by forming the covering layer 42 having the recessed portion 42d narrowing toward the bottom portion 42b by the electroless plating, the inside of the via 10v can be completely filled with the filling layer 43 of gold, which is formed by the electroplating and has a larger crystal grain size than that of the covering layer 42, without a void.

As a result, an inductor component of the via 10v is reduced, and high-frequency characteristics are improved. Then, for example, an improvement in heat dissipation by about 10% is expected with respect to a hollow via structure (R. Baskaran, Allen W. Hanson, CS MANTECH Conference (U.S.), May 18-21, 2015 “Simulation of the Impact of Through-Substrate Vias on the Thermal Resistance of Compound Semiconductor Devices”). Furthermore, since the covering layer 42 is formed of gold, a concern about reduced electrical reliability due to copper contamination are eliminated.

### Embodiment 2

In Embodiment 1 described above, an example has been described in which a portion covered with the covering layer is left on the rear face of the wafer. In Embodiment 2, an example in which the covering layer is removed from the rear face of the wafer will be described.

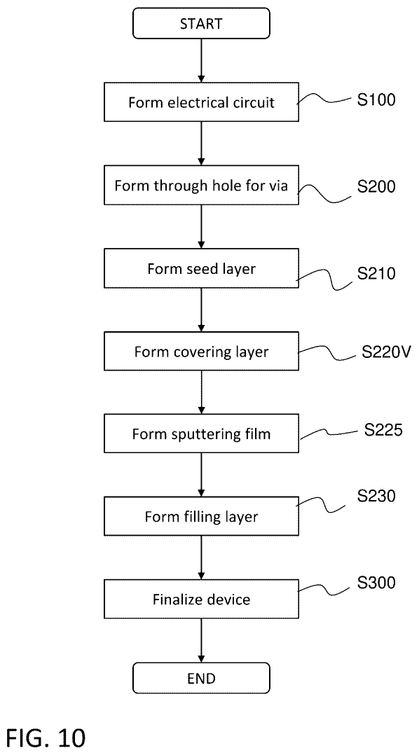

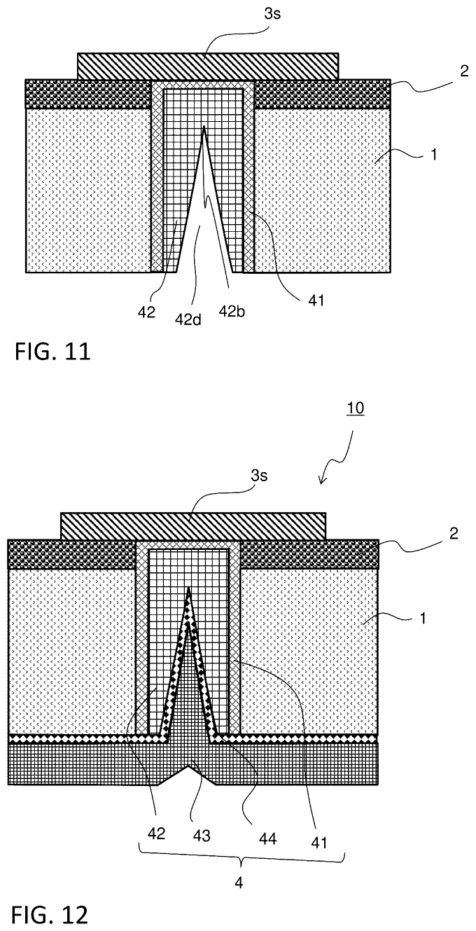

FIG. 10 to FIG. 12 are diagrams for describing a semiconductor device and a method of manufacturing the semiconductor device according to Embodiment 2, and FIG. 10 is a flowchart for describing the method of manufacturing the semiconductor device. FIG. 11 is an end view corresponding to FIG. 3 used in the description of Embodiment 1, for describing a structure after the formation of the covering layer and before the formation of the filling layer in the via filling process of the semiconductor device, and FIG. 12 is an end view corresponding to FIG. 1 used in the description of Embodiment 1, for describing a structure of a via. Note that the same components as those in Embodiment 1 are denoted by the same reference numerals, the description of the same components is omitted, and FIG. 2 and FIG. 4 used in Embodiment 1 will be referred to.

The structure of the semiconductor device 10 according to Embodiment 2 will be described together with the manufacturing process. As shown in the flowchart of FIG. 10, the process up to the formation of the seed layer 41 is the same as that of Embodiment 1. Also in the formation of the covering layer 42 (step S220V), the same procedure is followed until the covering layer 42 of gold is formed so as to have the recessed portion 42d opened toward the rear face side and to cover the rear face of the wafer as described in FIG. 4 of Embodiment 1. However, in the process of forming the covering layer 42 according to Embodiment 2 (step S220V), as shown in FIG. 11, among the covering layer 42 and the seed layer 41, a process of adjusting the covering range by removing layers deposited on the surface (wafer rear face) by etching is added.

Dry etching or wet etching is used for the etching. For example, argon ion milling or the like is used for the dry etching. Using the dry etching, titanium, gold, and platinum can be etched simultaneously. In the wet etching, a chemical solution to be used is changed depending on the target layer to be removed. For example, an iodine-based chemical solution is used for gold, and buffered hydrofluoric acid (BHF) or a mixed solution of ammonia (NH3) and hydrogen peroxide (H₂O₂) is used for titanium.

Note that the seed layer 41 may not necessarily be etched. For example, by etching only gold with the iodine-based chemical solution, it is possible to obtain a ground surface layer (titanium or platinum in this example) for gold as the seed layer 41 on the flat portion of the rear face of the wafer. Since gold is deposited in the through hole in a thickness larger than that of the flat portion, the surface of the through hole is mainly gold.

Thereafter, as in the case of forming the seed layer 41, a metal film 44 is formed on the covering layer 42 and the rear face of the wafer by a sputtering method as shown in FIG. 12 (step S225). For example, a titanium layer having a thickness of 50 nm and a gold layer having a thickness of 200 nm are used.

Thereafter, as in Embodiment 1, the filling layer 43 for filling the recessed portion 42d is formed by the electroplating of gold (step S230). Also in this case, when the film thickness of the filling layer 43 is too large, etching may be performed until the desired film thickness is obtained. For example, argon ion milling or the like is used for the dry etching, and for example, iodine-based wet etching or the like is used for the wet etching.

Here, in the electroless gold plating for forming the covering layer 42, when the thickness of the flat portion of the rear face of the wafer is increased to, for example, about 5 μm, the internal stress of the plating film is high, which causes wafer warpage and chip warpage. These are factors that lead to cracks, abnormal thermal resistance properties, and deterioration in handling efficiency.

In contrast, in the semiconductor device 10 or the method of manufacturing the semiconductor device according to Embodiment 2, the plating film on the flat portion of the rear face of the wafer is etched back to reduce the thickness of the gold in the flat portion and to improve the above-described problems. On the other hand, when the etch back is performed, the gold of the flat portion is removed, and therefore, with the state as it is, the electrical resistance of the flat portion increases, which hinders power supply in the electroplating of the next process. Therefore, like the case of reconstructing the seed layer 41, by forming the metal film 44 using sputtering or vapor deposition, the uniformity of the film and the filling property in the via 10v can be ensured in the electroplating in the process of forming the filling layer 43 (step S230).

That is, by removing the portion of the covering layer 42 covering the flat portion on the rear face of the wafer, the wafer warpage is reduced, and thus the wafer crack and the chip crack can be suppressed. Further, since the uniformity of the plating thickness of the flat portion within the wafer face is improved, it contributes to the uniformity of the chip characteristics and the high yield.

### Embodiment 3

In Embodiment 1 and Embodiment 2 described above, although the manufacturing method is different and the crystal grain size is different, the example has been described in which the filling layer is formed of the same gold as the covering layer. In Embodiment 3, an example in which the filling layer is formed of copper will be described.

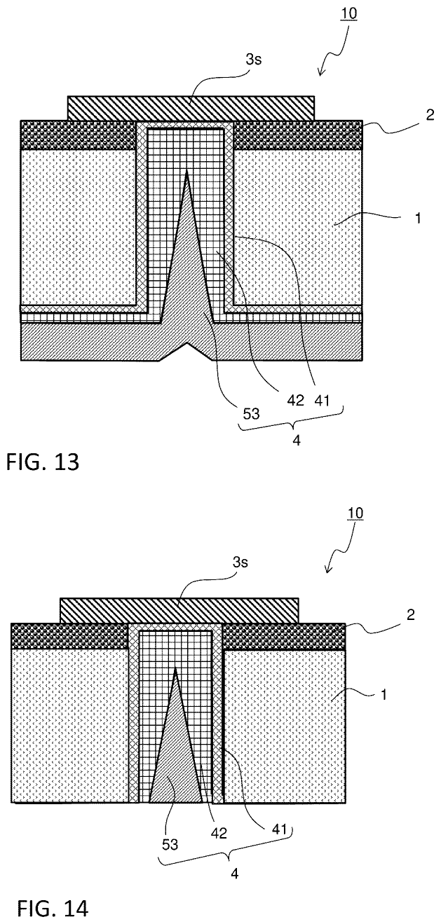

FIG. 13 and FIG. 14 are diagrams for describing a semiconductor device and a method of manufacturing the semiconductor device according to Embodiment 3, FIG. 13 is an end view corresponding to FIG. 1 used for describing Embodiment 1, for describing a structure of a via of the semiconductor device, and FIG. 14 is an end view corresponding to FIG. 13 for describing a structure of a via of a semiconductor device according to a variation. Note that the same components as those in Embodiment 1 are denoted by the same reference numerals, the description of the same components is omitted, and FIG. 2 to FIG. 4 used in Embodiment 1 will be referred to.

In Embodiment 3, the structure of the covering layer 42 and the manufacturing method thereof (up to step S220) are the same as those in Embodiment 1. However, in Embodiment 1, in the process of forming a filling layer 53, although electroplating is performed, the filling layer 53 of copper is formed by electroplating of copper (electrolytic copper plating) as shown in FIG. 13.

### Variation

Note that from the state shown in FIG. 13 where the filling layer 53 is formed, chemical mechanical polishing (CMP) may be performed to completely planarize the flat portion on the rear face of the wafer, as shown in FIG. 14.

By forming the covering layer 42 having the recessed portion 42d narrowing toward the bottom portion 42b by the electroless plating as in Embodiment 1, the inside of the via 10v can be completely filled with the filling layer 53 of copper formed by the electroplating without a void. Further, in Embodiment 3, since the filling layer 53 is formed of copper, the CMP can be performed without using a special chemical, and therefore, the surface can be easily planarized. Further, in the electroplating, an additive that is more effective in filling the via than gold plating is being developed for copper plating, and the recessed portion 42d is more easily filled.

That is, in the semiconductor device 10 or the method of manufacturing the semiconductor device according to Embodiment 3, the inductor component of the via 10v is reduced, and high-frequency characteristics are improved. Compared to the case where the entire filling part 4 is formed of copper, the gold covering layer 42 serves as a diffusion barrier for copper in addition to a conductive nitride film shown in Patent Document 2, and thus the reliability of the device is improved.

Further, since copper is superior to gold in the electrical conductivity and the thermal conductivity, device characteristics (electrical characteristics, high-frequency characteristics, and thermal characteristics) are improved as compared with the case where the filling part 4 is formed only of gold. Moreover, since the rear face of the wafer can be easily planarized, it becomes possible to design a three-dimensional device in which a subsequent layer is to be stacked on the planarized layer.

### Embodiment 4

In Embodiment 3 described above, the example has been described in which the filling layer of the semiconductor device of Embodiment 1 is replaced with copper. In Embodiment 4, an example in which the filling layer of the semiconductor device of Embodiment 2 is replaced with copper will be described.

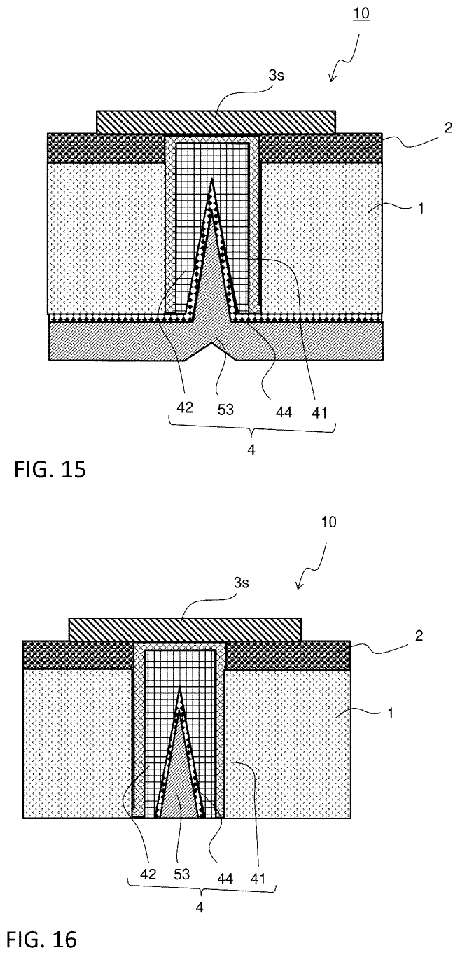

FIG. 15 and FIG. 16 are diagrams for describing a semiconductor device and a method of manufacturing the semiconductor device according to Embodiment 4, FIG. 15 is an end view corresponding to FIG. 12 used for describing Embodiment 2, for describing a structure of a via of the semiconductor device, and FIG. 16 is an end view corresponding to FIG. 15, for describing a structure of a via of a semiconductor device according to a variation. Note that the same components as those in Embodiment 1 and Embodiment 2 are denoted by the same reference numerals, the description of the same components is omitted, and FIG. 2 and FIG. 4 used in Embodiment 1 and FIG. 10 and FIG. 11 used in Embodiment 2 will be referred to.

In Embodiment 4, the structure of the covering layer 42 and the manufacturing method thereof (up to step S225) are the same as those in Embodiment 2. However, in Embodiment 4, in the process of forming the filling layer 53, although electroplating is performed, the filling layer 53 of copper is formed by the electroplating of copper (electrolytic copper plating) as shown in FIG. 15.

### Variation

Note that, from the state shown in FIG. 15 where the filling layer 53 is formed, the CMP may be performed to completely planarize the flat portion on the rear face of the wafer, as shown in FIG. 16.

By forming the covering layer 42 having the recessed portion 42d narrowing toward the bottom portion 42b by the electroless plating as in Embodiment 2, the inside of the via 10v can be completely filled with the filling layer 53 of copper formed by the electroplating without a void. Further, in Embodiment 4, since the filling layer 53 is formed of copper, the CMP polishing can be performed without using a special chemical, and therefore, the surface can be easily planarized. Further, in the electroplating, an additive that is more effective in filling the via than gold plating is being developed for copper plating, and the recessed portion 42d is more easily filled.

That is, in the semiconductor device 10 or the method of manufacturing the semiconductor device according to Embodiment 4, the inductor component of the via 10v is reduced, and high-frequency characteristics are improved. Compared to the case where the entire filling part 4 is formed of copper, the gold covering layer 42 serves as a diffusion barrier for copper in addition to the conductive nitride film, and thus the reliability of the device is improved.

Further, since copper is superior to gold in the electrical conductivity and the thermal conductivity, device characteristics (electrical characteristics, high-frequency characteristics, and thermal characteristics) are improved as compared with the case where the filling part 4 is formed only of gold. Moreover, since the rear face of the wafer can be easily planarized, it becomes possible to design a three-dimensional device in which a subsequent layer is to be stacked on the planarized layer.

### Embodiment 5

In Embodiment 3 and Embodiment 4 described above, examples have been described in which the composition of the filling layer is changed from gold to copper, compared to Embodiment 1 and Embodiment 2. In Embodiment 5, an example in which the composition of the filling layer is changed from gold to silver will be described.

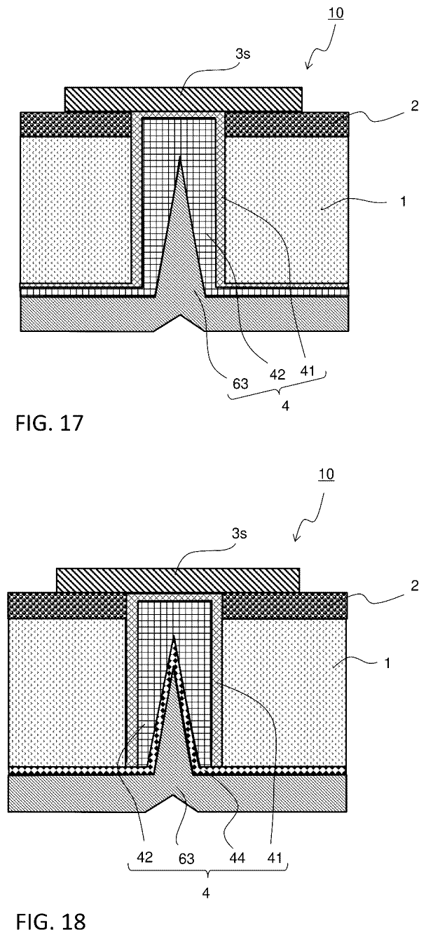

FIG. 17 and FIG. 18 are diagrams for describing a semiconductor device and a method of manufacturing the semiconductor device according to Embodiment 5, FIG. 17 is an end view corresponding to FIG. 1 used for describing Embodiment 1, for describing a structure of a via of the semiconductor device, and FIG. 18 is an end view corresponding to FIG. 12 used for describing Embodiment 2, for describing a structure of a via of a semiconductor device according to a variation. Note that the same components as those in Embodiment 1 and Embodiment 2 are denoted by the same reference numerals, the description of the same components is omitted, and FIG. 2 to FIG. 4 used in Embodiment 1 and FIG. 10 and FIG. 11 used in Embodiment 2 will be referred to.

In Embodiment 5, the structure of the covering layer 42 and the manufacturing method thereof (up to step S220) are the same as those in Embodiment 1. However, in Embodiment 5, in the process of forming a filling layer 63, although electroplating is performed, the filling layer 63 of silver is formed by electroplating of silver (electrolytic silver plating) as shown in FIG. 17.

### Variation

In the variation, the structure of the covering layer 42 and the manufacturing method thereof (up to step S225) are the same as those in Embodiment 2. However, in the present variation, in the process of forming the filling layer 63, although electroplating is performed, the filling layer 63 of silver is formed by the electroplating of silver (electrolytic silver plating) as shown in FIG. 18.

By forming the covering layer 42 having the recessed portion 42d narrowing toward the bottom portion 42b by the electroless plating as in Embodiment 1 and Embodiment 2, the inside of the via 10v can be completely filled with the filling layer 63 of silver formed by the electroplating without a void. Further, in Embodiment 5, since the filling layer 63 is formed of silver, the concern about reduced electrical reliability due to copper contamination are eliminated as in Embodiment 1 and Embodiment 2.

Further, since silver is superior to gold and copper in the electrical conductivity and the thermal conductivity, the inductor component of the via 10v are reduced and the device characteristics (electric characteristics, high-frequency characteristics, and thermal characteristics) are improved as compared with the case where the filling part 4 is formed of gold only or the case where the filling layer is formed of copper.

### Embodiment 6

In Embodiment 5 described above, the example has been described in which the composition of the filling layer is changed from gold to silver, compared with Embodiment 1 and Embodiment 2. In the Embodiment 6, an example in which the composition of the filling layer is changed from gold to nickel will be described.

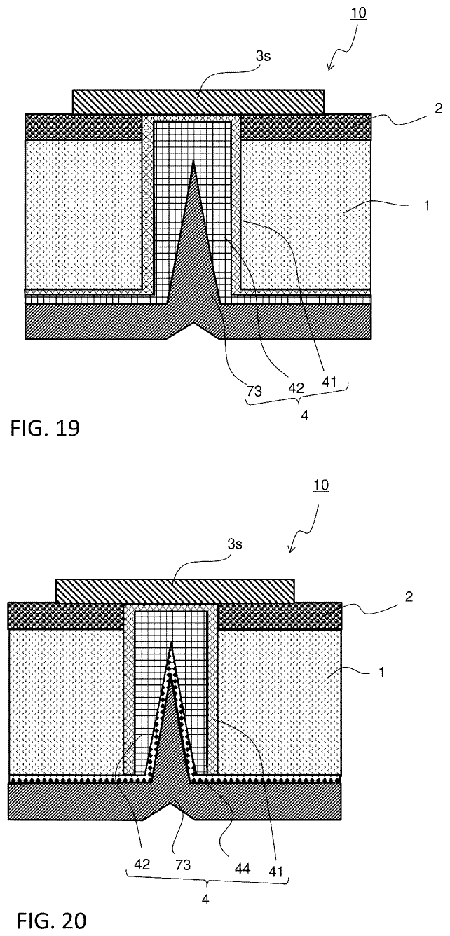

FIG. 19 and FIG. 20 are diagrams for describing a semiconductor device and a method of manufacturing the semiconductor device according to Embodiment 6, FIG. 19 is an end view corresponding to FIG. 1 used for describing Embodiment 1, for describing a structure of a via of the semiconductor device, and FIG. 20 is an end view corresponding to FIG. 12 used for describing Embodiment 2, for describing a structure of a via of a semiconductor device according to a variation. Note that the same components as those in Embodiment 1 and Embodiment 2 are denoted by the same reference numerals, the description of the same components is omitted, and FIG. 2 to FIG. 4 used in Embodiment 1 and FIG. 10 and FIG. 11 used in Embodiment 2 will be referred to.

Also in Embodiment 6, the structure of the covering layer 42 and the manufacturing method thereof (up to step S220) are the same as those in Embodiment 1. However, in Embodiment 6, in the process of forming a filling layer 73, although electroplating is performed, the filling layer 73 of nickel is formed by electroplating of nickel (Ni) (electrolytic nickel plating) as shown in FIG. 19.

### Variation

In the variation, the structure of the covering layer 42 and the manufacturing method thereof (up to step S225) are the same as those in Embodiment 2. However, in the present variation, in the process of forming the filling layer 73, although electroplating is performed, the filling layer 73 of nickel is formed by the electrolytic plating of nickel (electrolytic nickel plating) as shown in FIG. 20.

By forming the covering layer 42 having the recessed portion 42d narrowing toward the bottom portion 42b by the electroless plating as in Embodiment 1 and Embodiment 2, the inside of the via 10v can be completely filled with the filling layer 63 of silver formed by the electroplating without a void. Therefore, compared to the case of a hollow via structure, improvement in heat dissipation and high-frequency characteristics due to suppression of the inductor component are expected. Further, in Embodiment 6, since the filling layer 73 is formed of nickel, the concern about reduced electrical reliability due to copper contamination are eliminated as in Embodiment 1 and Embodiment 2.

The rear face of a high-frequency device is die-bonded using gold-tin (AuSn) solder, silver-tin (SnAg) solder, or similar materials, but when die bonding is performed on a gold or copper surface with solder, a thick alloy layer is formed at the interface, which causes poor electrical conductivity, poor adhesion, and deterioration of thermal properties. However, in Embodiment 6, nickel constituting the filling layer 73 functions as a barrier layer at the interface between gold and solder, and deterioration in these properties can be prevented.

### Embodiment 7

In Embodiment 5 and Embodiment 6 described above, the composition of the filling layer is changed from gold to silver in Embodiment 5, and from gold to nickel, compared to Embodiment 1 and Embodiment 2. In Embodiment 7, an example in which the composition of the filling layer is changed from gold to tin will be described.

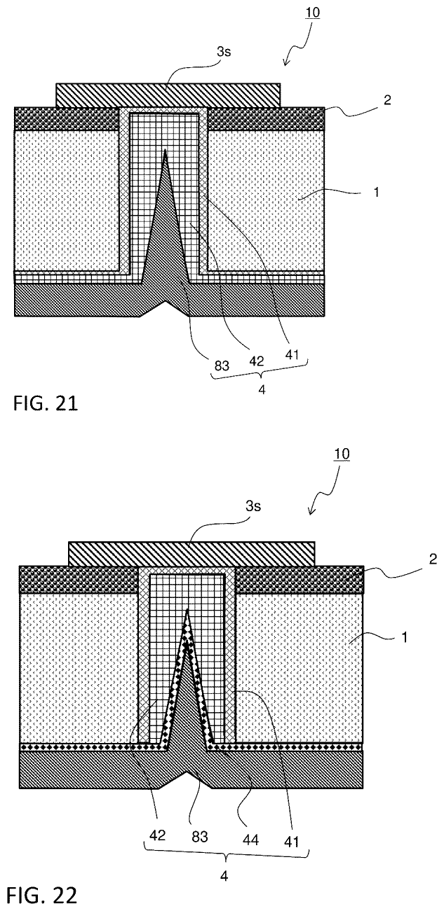

FIG. 21 and FIG. 22 are diagrams for describing a semiconductor device and a method of manufacturing the semiconductor device according to Embodiment 7, FIG. 21 is an end view corresponding to FIG. 1 used for describing Embodiment 1, for describing a structure of a via of the semiconductor device, and FIG. 22 is an end view corresponding to FIG. 12 used for describing Embodiment 2, for describing a structure of a via of a semiconductor device according to a variation. Note that the same components as those in Embodiment 1 and Embodiment 2 are denoted by the same reference numerals, the description of the same components is omitted, and FIG. 2 to FIG. 4 used in Embodiment 1 and FIG. 10 and FIG. 11 used in Embodiment 2 will be referred to.

In Embodiment 7, the structure of the covering layer 42 and the manufacturing method thereof (up to step S220) are the same as those in Embodiment 1. However, in Embodiment 7, in the process of forming a filling layer 83, although electroplating is performed, the filling layer 83 of tin is formed by electroplating of tin (electrolytic tin plating) as shown in FIG. 21.

### Variation

In the variation, the structure of the covering layer 42 and the manufacturing method thereof (up to step S225) are the same as those in Embodiment 2. However, in the present variation, in the process of forming the filling layer 83, although electroplating is performed, the filling layer 83 of tin is formed by the electroplating of tin (electrolytic tin plating) as shown in FIG. 22.

By forming the covering layer 42 having the recessed portion 42d narrowing toward the bottom portion 42b by the electroless plating as in Embodiment 1 and Embodiment 2, the inside of the via 10v can be completely filled with the filling layer 83 of tin formed by the electroplating without a void. Therefore, compared to the case of a hollow via structure, improvement in heat dissipation and high-frequency characteristics due to suppression of the inductor component are expected. Further, in Embodiment 7, since the filling layer 83 is formed of tin, the concern about reduced electrical reliability due to copper contamination are eliminated as in Embodiment 1 and Embodiment 2.

In addition, the rear face of the high-frequency device is die-bonded with gold-tin (AuSn) solder, silver-tin (SnAg) solder, or similar materials, but at this time, application of solder is not required. In addition, since the tin on the rear face of the wafer is a constituent material of the solder, it substantially forms solder directly on the device, resulting in good adhesion.

Note that, although various exemplary embodiments and examples are described in the present application, various features, aspects, and functions described in one or more embodiments are not inherent in an application of the contents disclosed in a particular embodiment, and can be applicable alone or in their various combinations to each embodiment. Accordingly, countless variations that are not illustrated are envisaged within the scope of the art disclosed in the specification of the present application. For example, the case where at least one component is modified, added or omitted, and the case where at least one component is extracted and combined with a component disclosed in another embodiment are included.

As described above, according to the semiconductor device 10 of the present application includes the substrate 1 made of a semiconductor material, the wiring member formed on one face of the substrate 1, and the solid via 10v having the first plating layer (covering layer 42) made of gold that has the opening on the other face of the substrate 1, covers the inner wall of the cylindrical hole having the bottom face as the wiring member (front-face electrode 3), and forms the recessed portion 42d recessed from a side of the opening toward the bottom face, and the second plating layer (filling layers 43, 53, 63, 73, and 83) made of any one of copper, silver, nickel, tin, and gold, the gold having a crystal grain size larger than that of the first plating layer (covering layer 42), the second plating layer filling the recessed portion (42d). Therefore, the concern about copper contamination is eliminated, and thus a semiconductor device having good electrical connection and heat dissipation in the thickness direction through the via 10v can be obtained at a low cost.

In particular, when the recessed portion 42d is formed so as to be widened from the bottom face toward the opening, a void is not generated, and a semiconductor device having excellent electrical conductivity and heat dissipation can be reliably obtained.

In addition, when the thickness t42 of the first plating layer (covering layer 42) to the bottom face of the recessed portion is set to be one fourth or more of the thickness of the substrate (via height Hv), the occurrence of a void can be more reliably prevented.

When the metal film 44 containing any one of titanium, tantalum, tungsten, chromium, and platinum and interposed between the first plating layer (covering layer 42) and the second plating layer (filling layers 43, 53, 63, 73, and 83) is provided, the plating film of the filling layer 43 is made uniform, and the filling property in the via 10v is further improved.

When the substrate 1 is any one of silicon carbide, indium phosphide, gallium nitride, germanium silicide, germanium, and silicon, a semiconductor device having higher performance is obtained.

As described above, the method of manufacturing the semiconductor device 10 of the present application is configured to include the processes of forming the wiring member on one face of the substrate 1 and forming the cylindrical hole that has the opening on the other face of the substrate 1 and has the wiring member (front-face electrodes 3) as the bottom face (step S100 to step S200), forming the first plating layer (covering layer 42) of gold by the electroless plating so as to cover the inner wall of the cylindrical hole and form the recessed portion 42d recessed from a side of the opening toward the bottom face (step S220, step S220V), and forming the second plating layer (filling layer 43) of any one of copper, silver, nickel, tin, and gold by the electroplating so as to fill the recessed portion 42d (step S230). Therefore, the concern about copper contamination is eliminated, and thus a semiconductor device having good electrical connection and heat dissipation in the thickness direction through the via 10v can be obtained at a low cost.

When the method includes a step of forming the metal film 44 covering the inner surface of the recessed portion 42d by sputtering or vapor deposition (step S225), the plating film is made uniform when the filling layer 43 is formed by the electroplating, and the filling property in the inside of the via 10v is further improved.

Description of Reference Numerals and Sign

1: substrate, 10: semiconductor device, 10v: via, 2: epitaxially grown
layer, 3: front-face electrode (wiring member), 4: filling part, 41: seed
layer, 42: covering layer (first plating layer), 42d: recessed portion,
43: filling layer (second plating layer), 44: metal film, 53: filling layer
(second plating layer), 63: filling layer (second plating layer), 73: filling
layer (second plating layer), 83: filling layer (second plating layer),
Dd: depth, Hv: via height, t42: thickness, Wd: opening width

1. A semiconductor device comprising:
a substrate made of a semiconductor material;
a wiring member formed on one face of the substrate; and
a solid via having a first plating layer made of gold that has an opening on the other face of the substrate, covers an inner wall of a cylindrical hole having a bottom face as the wiring member, and forms a recessed portion recessed from a side of the opening toward the bottom face, and a second plating layer made of any one of copper, silver, nickel, tin, and gold, the gold having a crystal grain size larger than that of the first plating layer, the second plating layer filling the recessed portion, and a metal film that contains any one of titanium, tantalum, tungsten, chromium, and platinum and is interposed between the first plating layer and the second plating layer.

2. The semiconductor device according to claim 1, wherein the recessed portion widens from the bottom face toward the opening.

3. The semiconductor device according to claim 1, wherein a thickness of the first plating layer to the bottom face of the recessed portion is one fourth or more of a thickness of the substrate.

4. (canceled)

5. The semiconductor device according to claim 1, wherein the substrate is any one of silicon carbide, indium phosphide, gallium nitride, germanium silicide, germanium, or silicon.

6. A method of manufacturing a semiconductor device, comprising steps of:
forming a wiring member on one face of a substrate made of a semiconductor material and forming a cylindrical hole that has an opening on the other face of the substrate and has the wiring member as a bottom face;
forming a first plating layer of gold by electroless plating so as to cover an inner wall of the cylindrical hole and form a recessed portion recessed from a side of the opening toward the bottom face; and
forming a second plating layer of any one of copper, silver, nickel, tin, and gold by electroplating so as to fill the recessed portion.

7. The method of manufacturing a semiconductor device according to claim 6, further comprising a step of forming a metal film covering an inner surface of the recessed portion by sputtering or vapor deposition.

8. The semiconductor device according to claim 2, wherein a thickness of the first plating layer to the bottom face of the recessed portion is one fourth or more of a thickness of the substrate.

9. The semiconductor device according to claim 2, wherein the substrate is any one of silicon carbide, indium phosphide, gallium nitride, germanium silicide, germanium, or silicon.

10. The semiconductor device according to claim 3, wherein the substrate is any one of silicon carbide, indium phosphide, gallium nitride, germanium silicide, germanium, or silicon.

11. The semiconductor device according to claim 8, wherein the substrate is any one of silicon carbide, indium phosphide, gallium nitride, germanium silicide, germanium, or silicon.
